(19) United States
(12) Patent Application Publication
(10) Pub. No.: US 2024/0066553 A1
(43) Pub. Date: Feb. 29, 2024

(54) Vibrator Device

(71) Applicant: SEIKO EPSON CORPORATION, Tokyo (JP)

(72) Inventors: Atsushi MATSUO, Shiojiri (JP); Kensaku ISOHATA, Minowa (JP); Norihito MATSUKAWA, Shimosuwa (JP)

(21) Appl. No.: 18/454,129

(22) Filed: Aug. 23, 2023

(30) Foreign Application Priority Data
Aug. 24, 2022 (JP) 2022-133066

(51) Int. Cl. B06B 1/06

(52) U.S. Cl. CPC B06B 1/0648

(57) ABSTRACT

A vibrator device includes a vibrator element including a vibrator section having a rectangular shape in a plan view, a linkage arm extending from a corner portion of the vibrator section in a first direction, and a support arm extending from the linkage arm in a second direction that intersects with the first direction, a container that houses the vibrator element, and an adhesive member that is shifted from the linkage arm in the second direction, is bonded to the support arm of the vibrator element, and bonds the vibrator element to the container, and an adhesive area of the region where the adhesive member is bonded to the support arm is greater than or equal to 20% of the area of the support arm in the plan view.

The present application is based on, and claims priority from JP Application Serial Number 2022-133066, filed Aug. 24, 2022, the disclosure of which is hereby incorporated by reference herein in its entirety.

### BACKGROUND

### 1. Technical Field

The present disclosure relates to a vibrator device.

### 2. Related Art

JP-A-2015-186196 describes a piezoelectric device that is a vibrator device with the effect of support stress on the vibration suppressed, the vibrator device incorporating a piezoelectric vibrator element including a vibrator section provided with a pair of excitation electrodes, a support section extending at a location separate from the vibrator section, and a linkage section extending to link one end of the support section to an end of the vibrator section, with draw-out electrodes drawn from the pair of excitation electrodes to a joint surface of the support section.

JP-A-2015-186196 is an example of the related art.

The piezoelectric device described in JP-A-2015-186196 can suppress the effect of the support stress on primary vibration, but cannot suppress unwanted spurious vibration that occurs in the vicinity of the primary vibration.

### SUMMARY

A vibrator device includes a vibrator element including a vibrator section having a rectangular shape in a plan view, a linkage arm extending from a corner portion of the vibrator section in a first direction, and a support arm extending from the linkage arm in a second direction that intersects with the first direction, a container that houses the vibrator element, and an adhesive member that is shifted from the linkage arm in the second direction, is bonded to the support arm of the vibrator element, and bonds the vibrator element to the container, and an adhesive area of the region where the adhesive member is bonded to the support arm is greater than or equal to 20% of the area of the support arm in the plan view.

### BRIEF DESCRIPTION OF THE DRAWINGS

FIG. 1 is a plan view showing the configuration of a vibrator device according to a first embodiment.

FIG. 2 is a cross-sectional view of the vibrator device taken along the line A-A in FIG. 1.

FIG. 3 is a cross-sectional view of the vibrator device taken along the line B-B in FIG. 1.

FIG. 4 is a plan view for describing the area of a support arm of a vibrator element and an adhesive area of an adhesive member.

FIG. 5 shows the relationship of the Q value of spurious vibration with the area ratio between the area of the support arm and the adhesive area of the adhesive member.

FIG. 6 is a plan view showing the configuration of the vibrator device according to a second embodiment.

FIG. 7 is a plan view showing the configuration of the vibrator device according to a third embodiment.

FIG. 8 is a plan view showing the configuration of the vibrator device according to a fourth embodiment.

FIG. 9 is a plan view showing the configuration of the vibrator device according to a fifth embodiment.

### DESCRIPTION OF EMBODIMENTS

### 1. First Embodiment

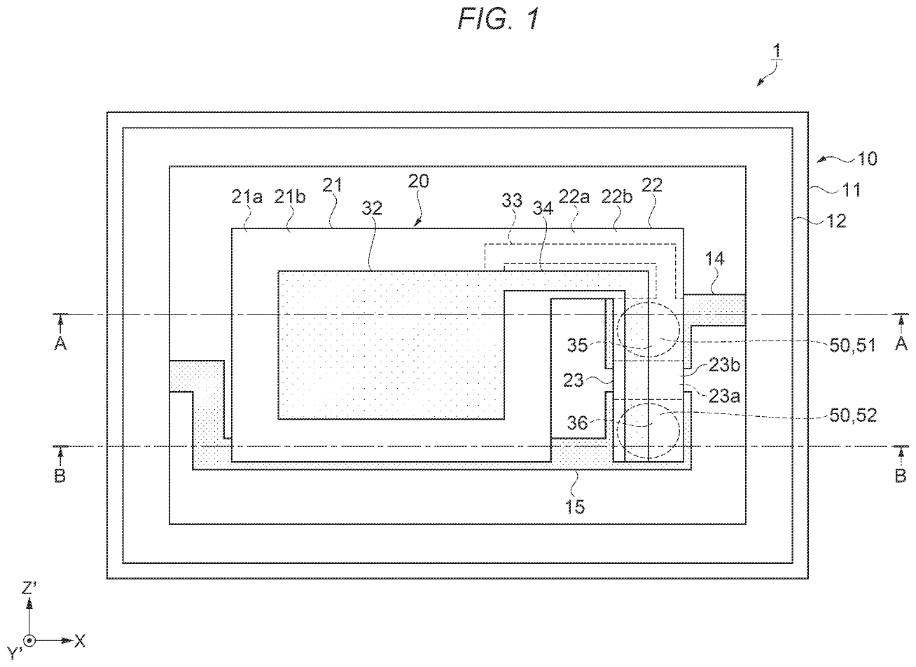

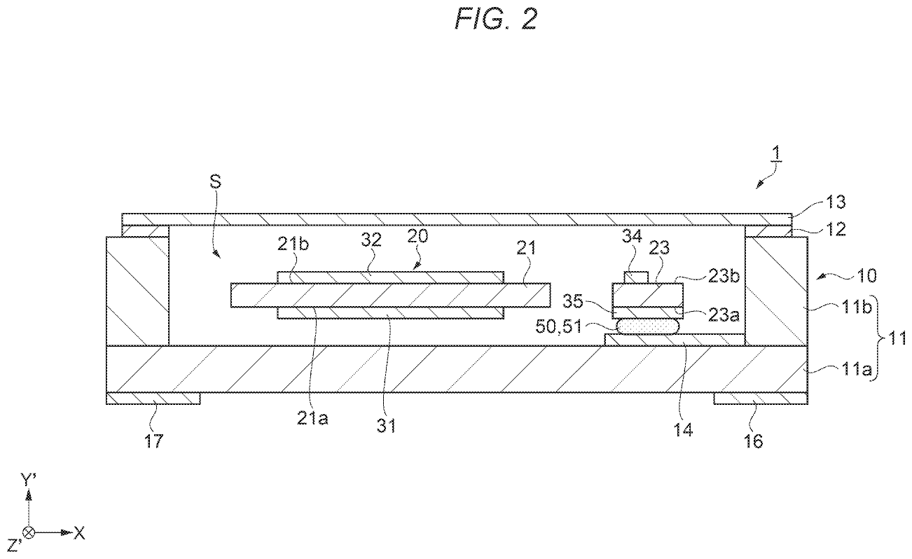

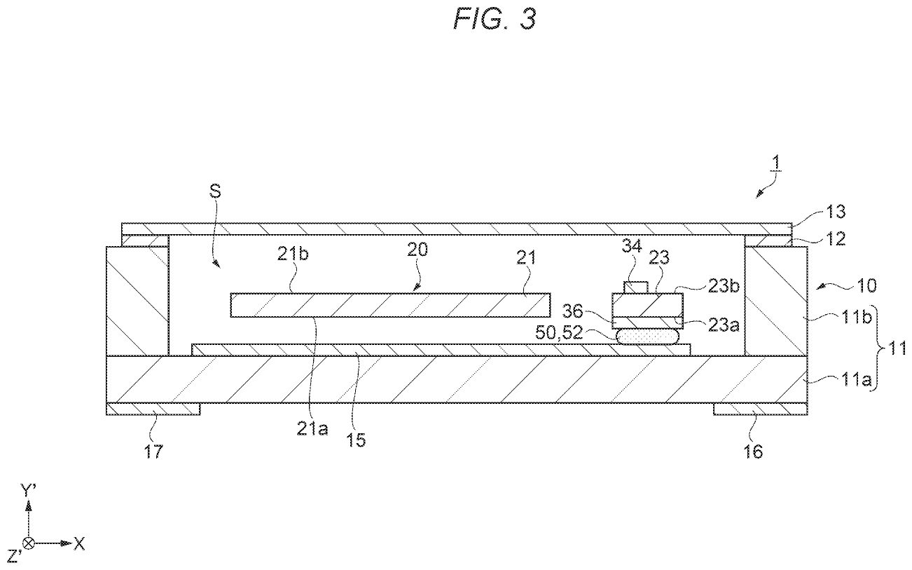

A vibrator device 1 according to a first embodiment will first be described with reference to FIGS. 1 to 5. The vibrator device 1 according to the present embodiment will be described with reference to a case where an AT-cut quartz crystal element is used as a vibrator element 20.

FIG. 1 shows the state in which a lid 13 is removed for convenience of description of the internal configuration of the vibrator device 1. The AT-cut quartz crystal element as the vibrator element 20 has a principal surface that is a plane XZ and inclines with respect to the axis Z out of crystal axes X, Y, and Z toward the axis Y by about 35° 15′ around the axis X. In the following description, new axes inclining with respect to the axial direction of the AT-cut quartz crystal vibrator element are used as axes Y′ and Z′, and the figures excluding FIG. 5 show the axes X, Y′, and Z′, which are perpendicular to each other. The longitudinal direction of the vibrator element 20 is called a “direction X” as the direction along the axis X, the thickness direction of the vibrator element 20 is called a “direction Y” as the direction along the axis Y′, and the direction perpendicular to the axes X and Y′ is called a “direction Z′” as the direction along the axis Z′. The side of the arrow attached to each of the axes is also called a “positive side”, and the side opposite from the arrow is also called a “negative side”. The positive side of the direction Y′ is also called an “upper side”, and the negative side of the direction Y′ is also called a “lower side”. In the present specification, a first direction is the direction X or the direction toward the positive side of the direction X, and a second direction that intersects with the first direction is the direction Z′ or the direction toward the negative side of the direction Z′.

The vibrator device 1 according to the present embodiment includes the vibrator element 20, a container 10, which houses the vibrator element 20, and an adhesive member 50, which bonds the vibrator element 20 to the container 10, as shown in FIGS. 1, 2, and 3.

The vibrator element 20 includes a rectangular vibrator section 21, a linkage arm 22 extending toward the positive side of the direction X, which is the first direction, from a corner portion that is an end portion of the vibrator element 21 that faces the positive side of the direction Z′ and the positive side of the direction X, and a support arm 23 extending toward the negative side of the direction Z′, which is the second direction, from an end portion of the linkage arm 22 that faces the positive side of the direction X and the negative side of the direction Z′.

The vibrator section 21 has a first principal surface 21a, which is the front side, and a second principal surface 21b, which is the rear side with respect to the front side, with a first excitation electrode 31 provided at the first principal surface 21a, a second excitation electrode 32 provided at the second principal surface 21b.

The support arm 23 has a first support principal surface 23a, which is the front side and is bonded to the container 10 via the adhesive member 50, and a second support principal surface 23b, which is the rear side with respect to the front side, and the first support principal surface 23a is provided with a first support electrode 35 electrically coupled to the first excitation electrode 31, and a second support electrode 36 electrically coupled to the second excitation electrode 32 and shifted from the first support electrode 35 toward the negative side of the direction Z′.

The first excitation electrode 31 and the first support electrode 35 are electrically coupled to each other via a first lead electrode 33 provided at a first linkage principal surface 22a of the linkage 22, and the second excitation electrode 32 and the second support electrode 36 are electrically coupled to each other via a second lead electrode 34 provided at a second linkage principal surface 22b of the linkage arm 22 and the second support principal surface 23b of the support arm 23. The second support electrode 36 provided at the first support principal surface 23a and the second lead electrode 34 provided at the second support principal surface 23b of the support arm 23 are electrically coupled to each other via a side electrode that is not shown but is provided at the side surface of the support arm 23.

The adhesive member 50 is an electrically conductive adhesive and includes a first adhesive 51, and a second adhesive 52 disposed separately from the first adhesive 51. The first adhesive 51 and the second adhesive 52 are each an electrically conductive adhesive. The first support electrode 35 is bonded to the container 10 via the first adhesive 51, and the second support electrode 36 is bonded to the container 10 via the second adhesive 52. More specifically, the first support electrode 35 and the second support electrode 36 provided at the support arms 23 are electrically coupled and mechanically bonded to internal electrodes 14 and 15 provided at the container 10 via the first adhesive 51 and the second adhesive 52, respectively. The vibrator element 20 is therefore bonded to the container 10 in the form of a cantilever with the support arm 23 serving as the fixed portion.

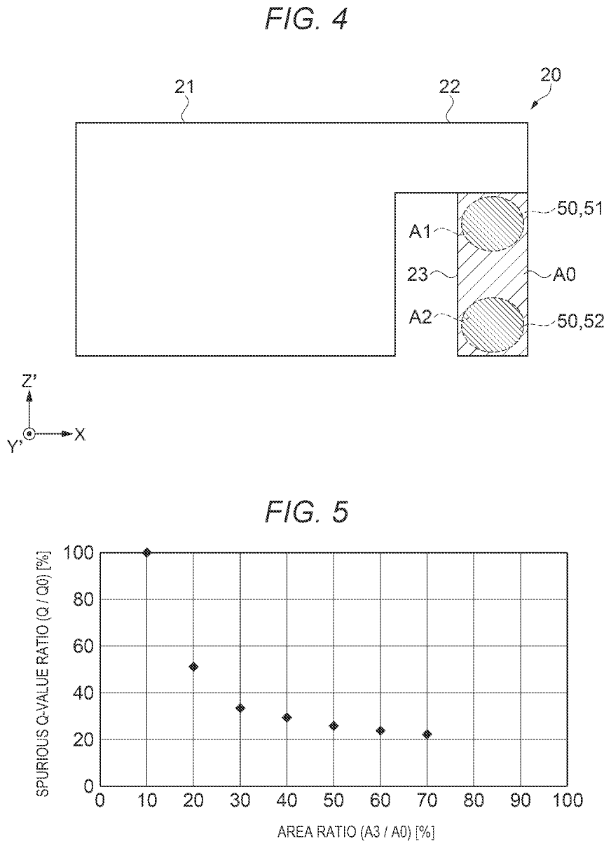

The relationship between an adhesive area A3 of the adhesive member 50 and the Q value of spurious vibration that occurs in the vicinity of primary vibration will now be described with reference to FIGS. 4 and 5. FIG. 5 shows the result of a simulation of calculating a Q-value ratio (Q/Q0) of the spurious vibration to each area ratio (A3/A0) with respect to Q0, which is the Q value of the spurious vibration for an area ratio (A3/A0) of 10%.

The vibrator element 20 is formed of the vibrator section 21, the linkage arm 22, and the support arm 23, and the area A0 of the support arm 23 is the area of a hatched portion extending from the linkage arm 22 toward the negative side of the direction Z′ in the plan view, as shown in FIG. 4.

The adhesive area A3 of the adhesive member 50 in the region where the adhesive member 50 is bonded to the support arm 23 is the sum of an adhesive area A1 of the first adhesive 51 and an adhesive area A2 of the second adhesive 52, the two areas hatched, in the plan view.

Next, the relationship between the area ratio (A3/A0) of the adhesive area A3 of the adhesive member 50 to the area A0 of the support arm 23 of the vibrator element 20 and the Q-value ratio (Q/Q0) of the spurious vibration with respect to the Q value Q0 of the spurious vibration for the area ratio (A3/A0) of 10% shows that the Q-value ratio for the area ratio (A3/A0) greater than or equal to 20% is smaller than or equal to approximately 50% of the Q-value ratio for the area ratio (A3/A0) is 10%, as shown in FIG. 5.

This is because when the area ratio (A3/A0) is greater than or equal to 20%, the adhesive member 50 provides a damping effect of attenuating the spurious vibration, and the damping effect provided by the adhesive member 50 can suppress the spurious vibration, which is unwanted vibration, by the configuration in which the adhesive area A3 of the region where the adhesive member 50 is bonded to the support arm 23 is greater than or equal to 20% of the area A0 of the support arm 23. The adhesive area A3 of the region where the adhesive member 50 is bonded to the support arm 23 is therefore greater than or equal to 20% of the area A0 of the support arm 23 in the present embodiment.

When the area ratio (A3/A0) is greater than or equal to 30%, the Q value of the spurious vibration is smaller than or equal to about ⅓ of the Q value for the area ratio (A3/A0) of 10%. The adhesive area A3 of the region where the adhesive member 50 is bonded to the support arm 23 is therefore more desirably greater than or equal to 30% of the area A0 of the support arm 23.

In the present embodiment, the adhesive area A3 of the region where the adhesive member 50 is bonded to the support arm 23 may be smaller than or equal to 70% of the area A0 of the support arm 23. A short circuit between the first adhesive 51 and the second adhesive 52 is thus readily prevented.

The container 10 includes a base substrate 11, which is a lamination of a plate-shaped first substrate 11a and a frame-shaped second substrate 11b, which constitutes a housing space S, a lid 13, which covers the housing space S, which houses the vibrator element 20, and a bonding member 12, which bonds the base substrate 11 and lid 13 to each other and makes the housing space S airtight.

The two internal electrodes 14 and 15 are provided at the upper surface of the first substrate 11a of the container 10, and two external terminals 16 and 17 are provided at the lower surface of the first substrate 11a. The internal electrode 14 is electrically coupled to the first support electrode 35 via the first adhesive 51 at the side opposite from the external terminal 16, and the internal electrode 15 is electrically coupled to the second support electrode 36 via the second adhesive 52 at the side opposite from the external terminal 17. The internal electrode 14 is electrically coupled to the external terminal 16 via a passing-through electrode that is not shown but passes through the first substrate 11a, and the internal electrode 15 is electrically coupled to the external terminal 17 via a passing-through electrode that is not shown but passes through the first substrate 11a.

As described above, the vibrator device 1 according to the present embodiment, in which the adhesive area A3 of the region where the adhesive member 50 is bonded to the support arm 23 is greater than or equal to 20% of the area A0 of the support arm 23, can suppress the spurious vibration, which is unwanted vibration with the aid of the damping effect provided by the adhesive member 50 and can be a vibrator device 1 that can suppress the spurious vibration.

Since the support arm 23 linked to the vibrator section 21 via the linkage arm 22 is bonded to the container 10 via the adhesive member 50, transmission of stress caused by the bonding to the vibrator section 21 can be suppressed, whereby a vibrator device 1 having stable vibration characteristics can be provided.

### 2. Second Embodiment

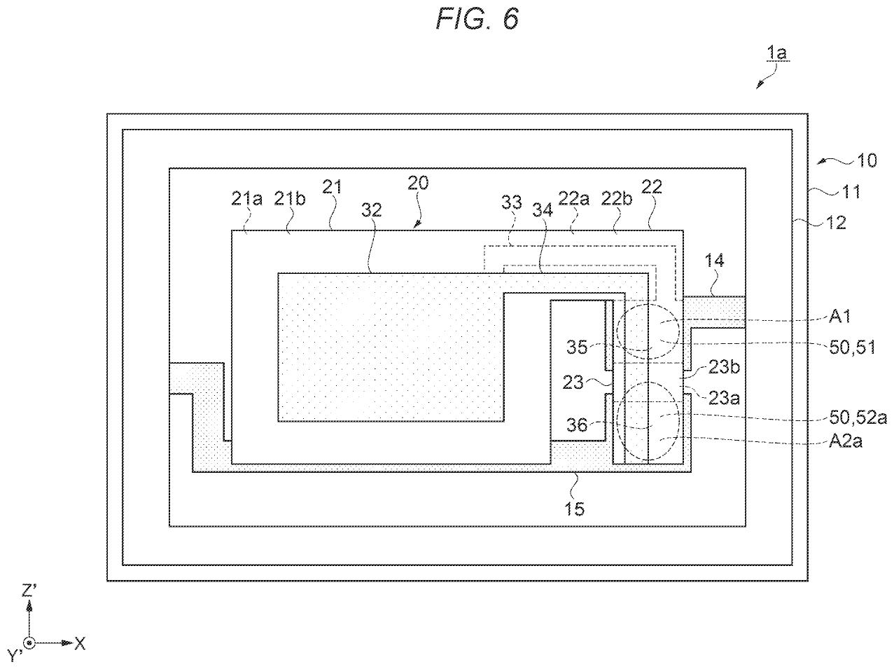

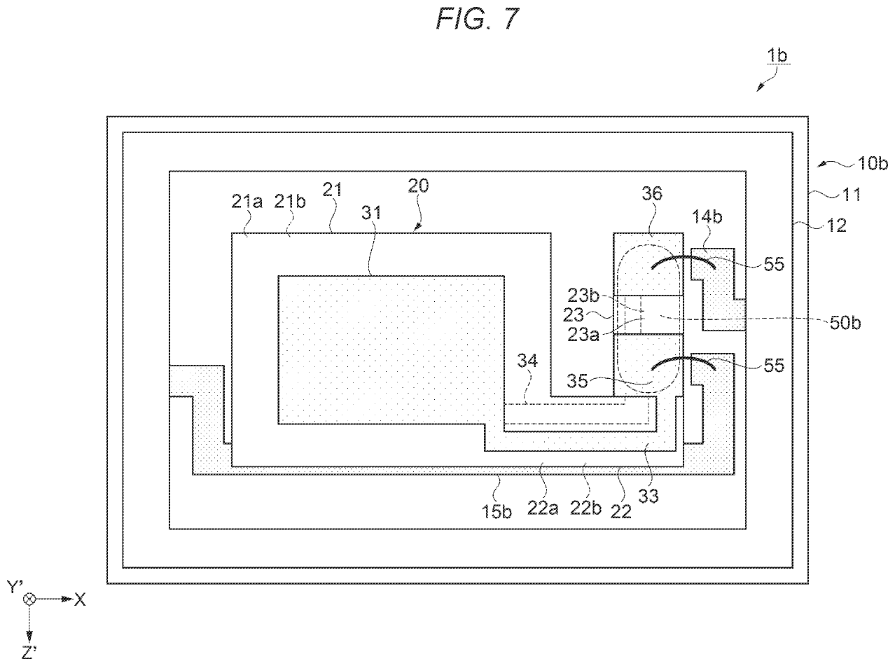

A vibrator device 1a according to a second embodiment will next be described with reference to FIG. 6.

FIG. 6 shows the state in which the lid 13 is removed for convenience of description of the internal configuration of the vibrator device 1a.

The vibrator device 1a according to the present embodiment is the same as the vibrator device 1 according to the first embodiment except that an adhesive area A2a of a second adhesive 52a is larger than the adhesive area A1 of the first adhesive 51. The difference from the first embodiment described above will be primarily described, and the same items will not be described.

In the vibrator device 1a according to the present embodiment, the adhesive area A2a of the second adhesive 52a is larger than the adhesive area A1 of the first adhesive 51 in the plan view, as shown in FIG. 6. The adhesive area A1 of the first adhesive 51 is equal to that in the first embodiment.

The configuration in which the adhesive area A2a of the second adhesive 52a, which is shifted from the first adhesive 51 toward the negative side of the direction Z′, is larger than the adhesive area A1 of the first adhesive 51 allows an increase in the adhesive area A3 of the adhesive member 50, whereby the adhesive strength can be further increased, and the damping effect provided by the adhesive member 50 can further suppress the spurious vibration. Even when the adhesive area A2a of the second adhesive 52a, which is separate from the linkage arm 22, is increased, the second adhesive 52a does not reach the linkage arm 22, so that the transmission of the stress caused by the bonding to the vibrator section 21 can be suppressed.

The configuration described above can further enhance the effect provided in the first embodiment.

### 3. Third Embodiment

A vibrator device 1b according to a third embodiment will next be described with reference to FIG. 7.

FIG. 7 shows the state in which the lid 13 is removed for convenience of description of the internal configuration of the vibrator device 1b.

The vibrator device 1b according to the present embodiment is the same as the vibrator device 1 according to the first embodiment except that the vibrator element 20 is reversed inside out, an adhesive member 50b is a non-electrically-conductive adhesive, the first support electrode 35 and the second support electrode 36 are electrically coupled to a container 10b via bonding wires 55, and the shapes of internal electrodes 14b and 15b differ from those in the first embodiment. The differences from the first embodiment described above will be primarily described, and the same items will not be described.

In the vibrator device 1b according to the present embodiment, the second principal surface 21b and the second support principal surface 23b of the vibrator element 20, which is the same as that in the first embodiment, are reversed inside out so that the two principal surfaces face the container 10b, and the second support principal surface 23b of the support arm 23 is bonded to the container 10b via the adhesive member 50b, as shown in FIG. 7. In the present embodiment, the adhesive member 50b is a non-electrically-conductive adhesive, but not necessarily, and may instead be an electrically conductive adhesive.

The first support electrode 35 and the second support electrode 36 provided at the first support principal surface 23a are disposed at the side opposite from the container 10b. Therefore, the first support electrode 35 is electrically coupled to the inner electrode 15b via one of the bonding wires 55, and the second support electrode 36 is electrically coupled to the inner electrode 14b via the other bonding wire 55.

Since the first support electrode 35 and the second support electrode 36 are electrically coupled to the internal electrodes 14b and 15b via the bonding wires 55, the adhesive area A3 of the adhesive member 50b, which bonds the support arm 23 to the container 10b, can be increased, whereby the adhesive strength can be further increased, and the damping effect provided by the adhesive member 50b can further suppress the spurious vibration.

The configuration described above can further enhance the effect provided in the first embodiment.

### 4. Fourth Embodiment

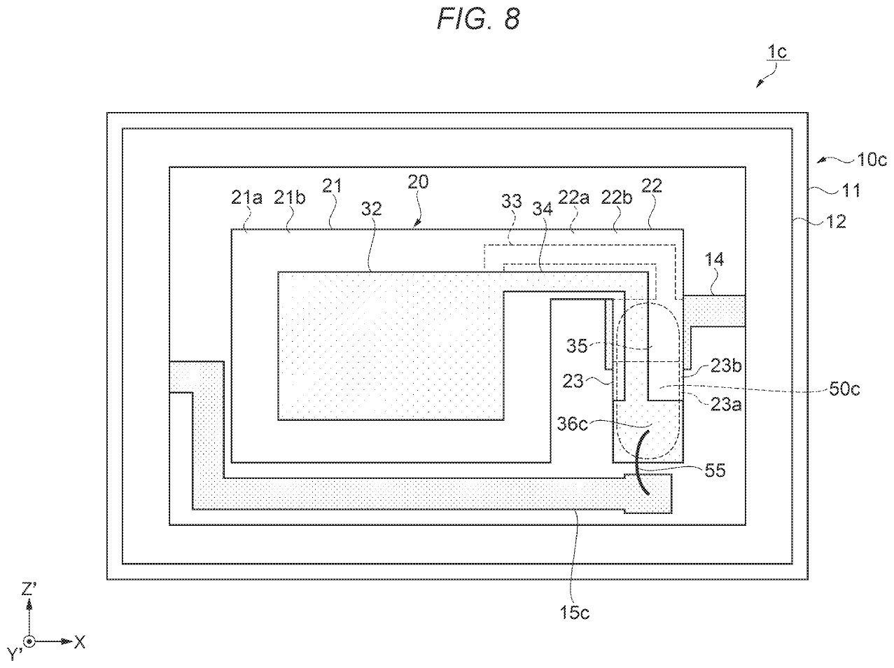

A vibrator device 1c according to a fourth embodiment will next be described with reference to FIG. 8.

FIG. 8 shows the state in which the lid 13 is removed for convenience of description of the internal configuration of the vibrator device 1c.

The vibrator device 1c according to the present embodiment is the same as the vibrator device 1 according to the first embodiment except that one adhesive member 50c is provided, a second support electrode 36c is disposed at the second support principal surface 23b, and the second support electrode 36c is electrically coupled to a container 10c via the bonding wire 55, and the shape of an internal electrode 15c differs from that in the first embodiment. The differences from the first embodiment described above will be primarily described, and the same items will not be described.

In the vibrator device 1c according to the present embodiment, the second support electrode 36c is disposed at the second support principal surface 23b, and the second support electrode 36c is electrically coupled to the container 10c via the bonding wire 55, as shown in FIG. 8.

The first support principal surface 23a of the support arm 23 is bonded to the container 10c via the adhesive member 50c, which is an electrically conductive adhesive. More specifically, the first support electrode 35 provided at the first support principal surface 23a is electrically coupled to the internal electrode 14 provided at the container 10c via the adhesive member 50c, and a portion of the first support principal surface 23a where the first support electrode 35 is not provided is bonded to the container 10c via the adhesive member 50c. The adhesive area A3 of the adhesive member 50c can therefore be increased, whereby the adhesive strength can be further increased, and the damping effect provided by the adhesive member 50c can further suppress the spurious vibration.

The configuration described above can further enhance the effect provided in the first embodiment. In the present embodiment, the support arm 23 is bonded to the container 10c via one adhesive member 50c, and the support arm 23 may instead be bonded to the container 10c via two adhesive members 50c, as in the first embodiment.

### 5. Fifth Embodiment

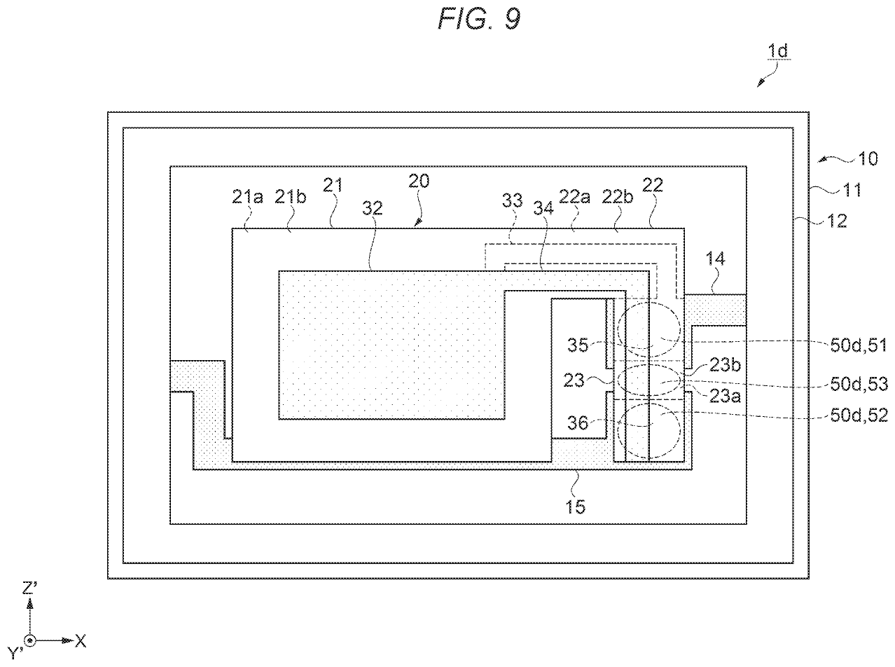

A vibrator device 1d according to a fifth embodiment will next be described with reference to FIG. 9.

FIG. 9 shows the state in which the lid 13 is removed for convenience of description of the internal configuration of the vibration device 1d.

The vibrator device 1d according to the present embodiment is the same as the vibrator device 1 according to the first embodiment except that a third adhesive 53 is disposed between the first adhesive 51 and the second adhesive 52. The difference from the first embodiment described above will be primarily described, and the same items will not be described.

In the vibrator device 1d according to the present embodiment, an adhesive member 50d, which causes the support arm 23 to adhere to the container 10, include the first adhesive 51, the second adhesive 52 disposed separately from the first adhesive 51, and the third adhesive 53 disposed separately from the first adhesive 51 and the second adhesive 52, as shown in FIG. 9. More specifically, the third adhesive 53 is disposed between the first adhesive 51 and the second adhesive 52.

The first adhesive 51 is an electrically conductive adhesive and electrically couples the first support electrode 35, which is provided at the first support principal surface 23a of the support arm 23, to the internal electrode 14 provided at the container 10. The second adhesive 52 is an electrically conductive adhesive and electrically couples the second support electrode 36, which is provided at the first support principal surface 23a of the support arm 23, to the internal electrode 15 provided at the container 10. The third adhesive 53 is a non-electrically-conductive adhesive and bonds the portion between the first support electrode 35 and the second support electrode 36, which are provided at the first support principal surface 23a of the support arm 23, to the container 10.

The configuration in which the third adhesive 53, which is a non-electrically-conductive adhesive, is disposed between the first adhesive 51 and the second adhesive 52 allows an increase in the adhesive area A3 of the adhesive member 50d with a short circuit between the first support electrode 35 and the second support electrode 36 prevented, whereby the adhesive strength can be further increased, and the damping effect provided by the adhesive member 50d can further suppress the spurious vibration. In the present embodiment, the third adhesive 53 is a non-electrically-conductive adhesive to prevent an inter-electrode short circuit, but not necessarily. The third adhesive 53 may instead be an electrically conductive adhesive as long as the distances between the first adhesive 51 and the third adhesive 53 and the distance between the second adhesive 52 and the third adhesive 53 are sufficiently ensured.

The configuration described above can further enhance the effect provided in the first embodiment.

What is claimed is:

1. A vibrator device comprising:
a vibrator element including a vibrator section having a rectangular shape in a plan view, a linkage arm extending from a corner portion of the vibrator section in a first direction, and a support arm extending from the linkage arm in a second direction that intersects with the first direction;
a container that houses the vibrator element; and
an adhesive member that is shifted from the linkage arm in the second direction, is bonded to the support arm of the vibrator element, and causes the vibrator element to adhere to the container,
wherein an adhesive area of a region where the adhesive member is bonded to the support arm is greater than or equal to 20% of an area of the support arm in the plan view.

2. The vibrator device according to claim 1, wherein the adhesive member is an electrically conductive adhesive.

3. The vibrator device according to claim 1, wherein in the plan view, the adhesive area of the region where the adhesive member is bonded to the support arm is greater than or equal to 30% of the area of the support arm.

4. The vibrator device according to claim 1, wherein the adhesive member includes a first adhesive, and a second adhesive disposed separately from the first adhesive.

5. The vibrator device according to claim 4,
wherein the vibrator section includes a first excitation electrode provided at a first principal surface that is a front side, and a second excitation electrode provided at a second principal surface that is a rear side with respect to the front side,
the support arm has a first support principal surface that is a front side and is bonded to the container via the adhesive member, a second support principal surface that is a rear side with respect to the front side, a first support electrode electrically coupled to the first excitation electrode, and a second support electrode electrically coupled to the second excitation electrode and shifted from the first support electrode in the second direction,
the first and second support electrodes are provided at the first support principal surface,
the first and second adhesives are each an electrically conductive adhesive,
the first support electrode is bonded to the container via the first adhesive, and
the second support electrode is bonded to the container via the second adhesive.

6. The vibrator device according to claim 5, wherein an adhesive area of the second adhesive is larger than an adhesive area of the first adhesive.

7. The vibration device according to claim 1,
wherein the vibrator section includes a first excitation electrode provided at a first principal surface that is a front side, and a second excitation electrode provided at a second principal surface that is a rear side with respect to the front side,
the support arm has a first support principal surface that is a front side and is bonded to the container via the adhesive member, a second support principal surface that is a rear side with respect to the front side, a first support electrode electrically coupled to the first excitation electrode, and a second support electrode electrically coupled to the second excitation electrode and shifted from the first support electrode in the second direction,
the first and second support electrodes are provided at the first support principal surface, and
the first and second support electrodes are electrically coupled to the container via bonding wires.

8. The vibrator device according to claim 7, wherein the adhesive member is a non-electrically-conductive adhesive.

9. The vibration device according to claim 1,
wherein the vibrator section includes a first excitation electrode provided at a first principal surface that is a front side, and a second excitation electrode provided at a second principal surface that is a rear side with respect to the front side,
the support arm has a first support principal surface that is a front side and is bonded to the container via the adhesive member, a second support principal surface that is a rear side with respect to the front side, a first support electrode electrically coupled to the first excitation electrode, and a second support electrode electrically coupled to the second excitation electrode and shifted from the first support electrode in the second direction,
the first support electrode is provided at the first support principal surface,
the second support electrode is provided at the second support principal surface,
the adhesive member is an electrically conductive adhesive,
the first support electrode is electrically connected to the container via the adhesive member, and
the second support electrode is electrically coupled to the container via a bonding wire.

10. The vibration device according to claim 1, wherein the adhesive member includes a first adhesive, a second adhesive disposed separately from the first adhesive, and a third adhesive disposed separately from the first and second adhesives.

11. The vibration device according to claim 10,
wherein the vibrator section includes a first excitation electrode provided at a first principal surface that is a front side, and a second excitation electrode provided at a second principal surface that is a rear side with respect to the front side,
the support arm has a first support principal surface that is a front side and is bonded to the container via the adhesive member, a second support principal surface that is a rear side with respect to the front side, a first support electrode electrically coupled to the first excitation electrode, and a second support electrode electrically coupled to the second excitation electrode and shifted from the first support electrode in the second direction,
the first and second support electrodes are provided at the first support principal surface,
the first support electrode is bonded to the container via the first adhesive,
the second support electrode is bonded to the container via the second adhesive,
the first support principal surface is bonded to the container via the third adhesive,
the first and second adhesives are each an electrically conductive adhesive, and
the third adhesive is a non-electrically-conductive adhesive.
